(19) United States
(12) Patent Application Publication
(10) Pub. No.: US 2026/0018498 A1
(43) Pub. Date: Jan. 15, 2026

(54) SEMICONDUCTOR DEVICE

(71) Applicant: Rohm Co., Ltd., Kyoto-shi (JP)

(72) Inventor: Yoshizo OSUMI, Kyoto-shi (JP)

(21) Appl. No.: 19/328,947

(22) Filed: Sep. 15, 2025

Related U.S. Application Data
(63) Continuation of application No. PCT/JP2024/007791, filed on Mar. 1, 2024.

(30) Foreign Application Priority Data
Mar. 22, 2023 (JP) 2023-045739

(51) Int. Cl. H01L 23/495; H01L 23/00; H01L 25/18

(52) U.S. Cl. CPC H01L 23/49575; H01L 24/48; H01L 25/18; H01L 23/49513; H01L 24/32; H01L 24/73; H01L 2224/32245; H01L 2224/48137; H01L 2224/48245; H01L 2224/73265

(57) ABSTRACT

The semiconductor device includes an element support, first and second semiconductor elements on the element support, an insulating element insulating the first and the second semiconductor elements from each other, and an insulating substrate. The insulating element includes a first transceiver electrically connected to the first semiconductor element, a second transceiver electrically connected to the second semiconductor element, and an interfacing member for transmitting and receiving signals between the first and the second transceivers. The interfacing member is closer to the element support than the first and the second transceivers. The insulating substrate is between the element support and the insulating element and bonded to the element support. The insulating element is bonded to the insulating substrate.

### TECHNICAL FIELD

The present disclosure relates to semiconductor devices.

### BACKGROUND ART

Inverter devices are used, for example, in electric vehicles, hybrid vehicles, and home appliances. Such inverter devices are provided with semiconductor devices. In addition, the inverter devices are equipped with switching elements such as IGBTs (Insulated Gate Bipolar Transistors) and MOSFETs (Metal Oxide Semiconductor Field Effect Transistors). Each of these semiconductor devices includes a controller and a gate driver. When the inverter device is used, control signals outputted from an external source are inputted to the controller of the semiconductor device. The controller converts the control signals into pulse width modulation (PWM) control signals and transmits them to the gate driver. The gate driver drives, for example, six switching elements at the desired timing based on the PWM control signal. As a result, three-phase AC power for driving a motor, for example, is generated from DC power. JP-A-2014-30049 discloses an example of a semiconductor device (driver circuit) used in a motor drive device.

### BRIEF DESCRIPTION OF THE DRAWINGS

FIG. 1 is a plan view of a semiconductor device according to a first embodiment of the present disclosure.

FIG. 2 is a plan view of the semiconductor device according to the first embodiment of the present disclosure.

FIG. 3 is a front view of the semiconductor device according to the first embodiment of the present disclosure.

FIG. 4 is a left side view of the semiconductor device according to the first embodiment of the present disclosure.

FIG. 5 is a right side view of the semiconductor device according to the first embodiment of the present disclosure.

FIG. 6 is a cross-sectional view along the VI-VI line in FIG. 2.

FIG. 7 is a cross-sectional view along the VII-VII line in FIG. 2.

FIG. 8 is an enlarged plan view showing parts of the semiconductor device according to the first embodiment of the present disclosure.

FIG. 9 is a cross-sectional view along the IX-IX line in FIG. 8.

FIG. 10 is a schematic diagram showing the insulating element and the insulating substrate of the semiconductor device according to the first embodiment of the present disclosure.

FIG. 11 is a circuit diagram illustrating the semiconductor device according to the first embodiment of the present disclosure.

FIG. 12 is a plan view showing a first variation of the semiconductor device according to the first embodiment of the present disclosure.

FIG. 13 is a cross-sectional view along line XIII-XIII in FIG. 12.

FIG. 14 is an enlarged plan view showing parts of the first variation of the semiconductor device according to the first embodiment of the present disclosure.

FIG. 15 is a partially enlarged cross-sectional view along line XV-XV in FIG. 14.

FIG. 16 is a schematic diagram showing the insulating element and the insulating substrate of the first variation of the semiconductor device according to the first embodiment of the present disclosure.

FIG. 17 is a plan view showing a semiconductor device according to a second embodiment of the present disclosure.

FIG. 18 is a cross-sectional view along the line XVIII-XVIII in FIG. 17.

FIG. 19 is a plan view of a first variation of the semiconductor device according to the second embodiment of the present disclosure.

FIG. 20 is a plan view of the second variation of the semiconductor device according to the second embodiment of the present disclosure.

FIG. 21 is a plan view of a semiconductor device according to a third embodiment of the present disclosure.

FIG. 22 is a cross-sectional view along line XXII-XXII in FIG. 21.

FIG. 23 is a plan view of a semiconductor device according to a fourth embodiment of the present disclosure.

FIG. 24 is a cross-sectional view along line XXIV-XXIV of FIG. 23.

FIG. 25 is a cross-sectional view showing a first variation of the semiconductor device according to the fourth embodiment of the present disclosure.

FIG. 26 is a plan view of a semiconductor device according to a fifth embodiment of the present disclosure.

FIG. 27 is a cross-sectional view along line XXVII-XXVII in FIG. 26.

FIG. 28 is a circuit diagram illustrating the semiconductor device according to the fifth embodiment of the present disclosure.

FIG. 29 is a cross-sectional view showing a first variation of the semiconductor device according to the fifth embodiment of the present disclosure.

FIG. 30 is a plan view showing a semiconductor device according to a sixth embodiment of the present disclosure.

FIG. 31 is a cross-sectional view along line XXXI-XXXI in FIG. 30.

### DETAILED DESCRIPTION OF EMBODIMENTS

The following describes preferred embodiments of the present disclosure in detail with reference to the drawings.

In the present disclosure, the terms such as “first”, “second”, and “third” are used merely as labels and are not intended to impose ordinal requirements on the items to which these terms refer.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”. Furthermore, in the description of the present disclosure, the expression “A surface A faces (a first side or a second side) in a direction B” is not limited to the situation where the angle of the surface A to the direction B is 90° and includes the situation where the surface A is inclined with respect to the direction B.

### First Embodiment

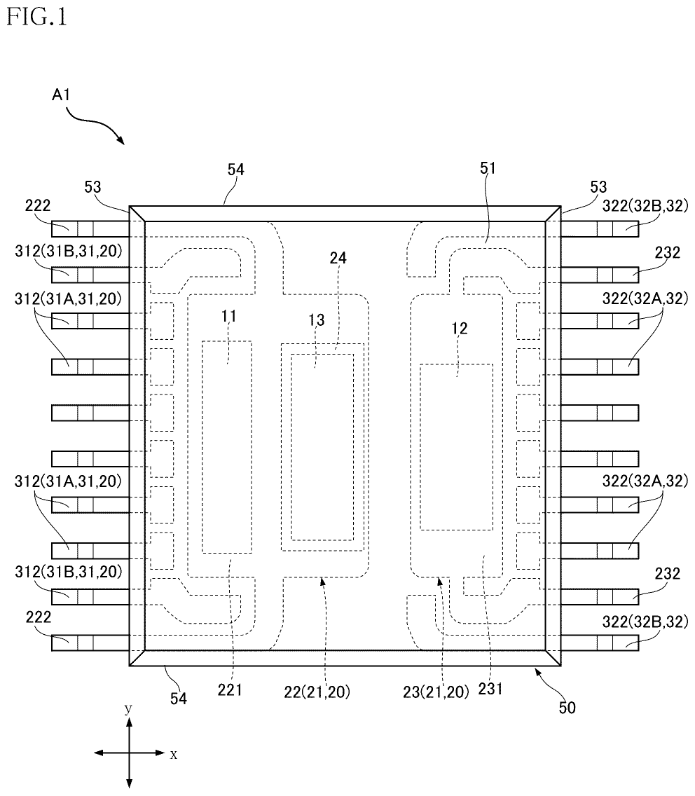

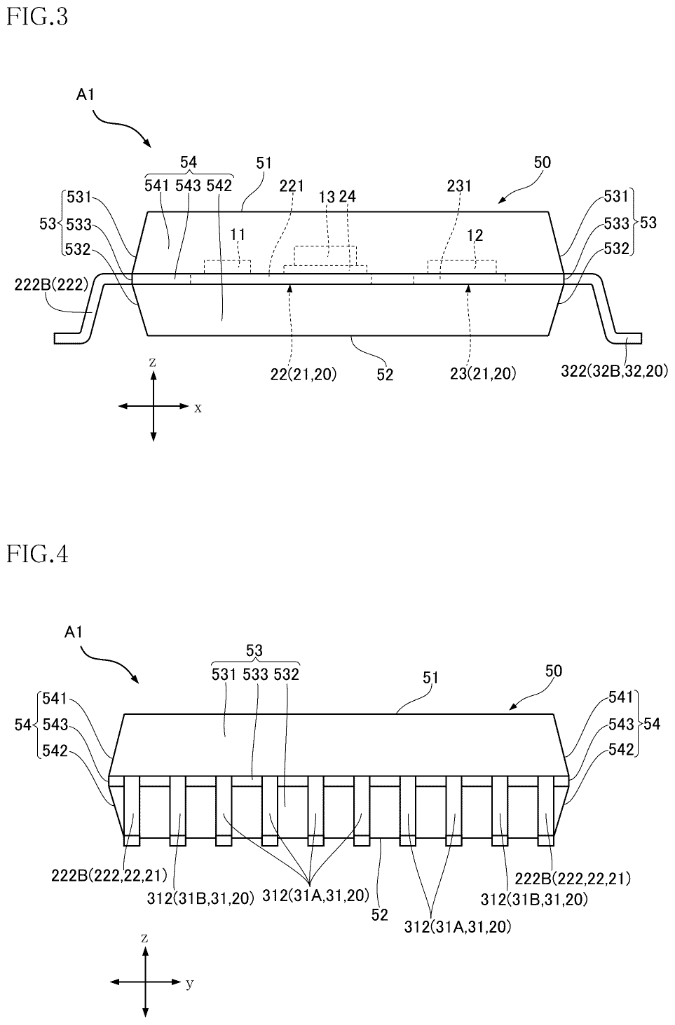

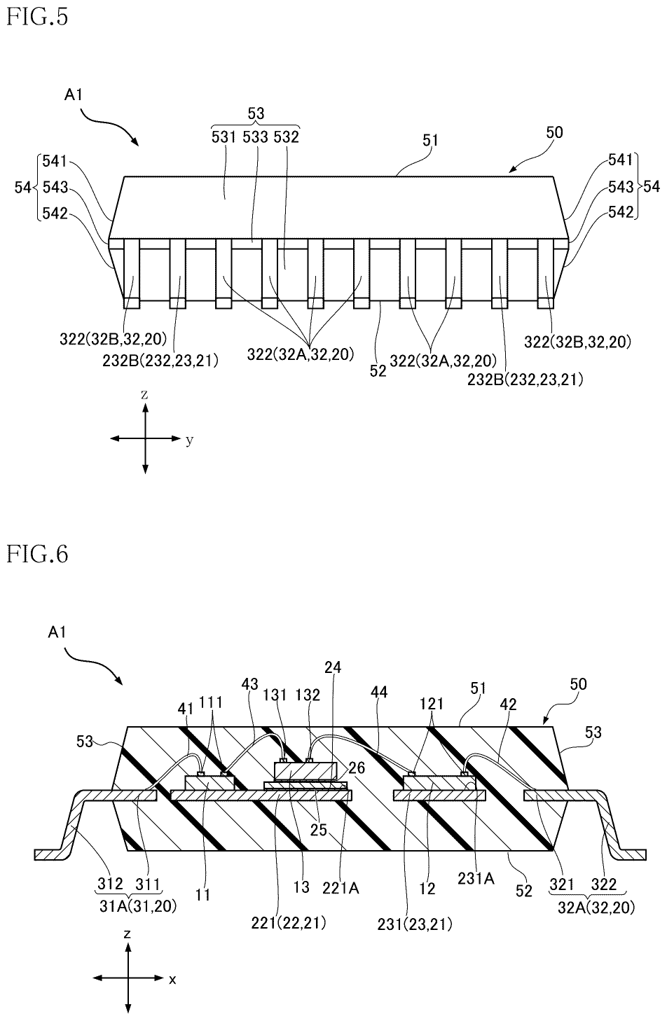

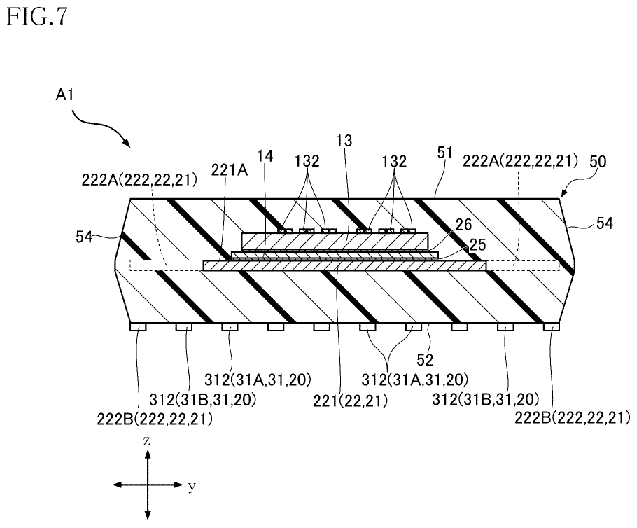

FIGS. 1 to 10 show a semiconductor device A1 according to a first embodiment of the present disclosure. The semiconductor device A1 of the present embodiment includes a first semiconductor element 11, a second semiconductor element 12, an insulating element 13, a plurality of conductive members 20, an insulating substrate 24, a first bonding layer 25, a second bonding layer 26, a plurality of first wires 41, a plurality of second wires 42, a plurality of third wires 43, a plurality of fourth wires 44, and a sealing resin 50.

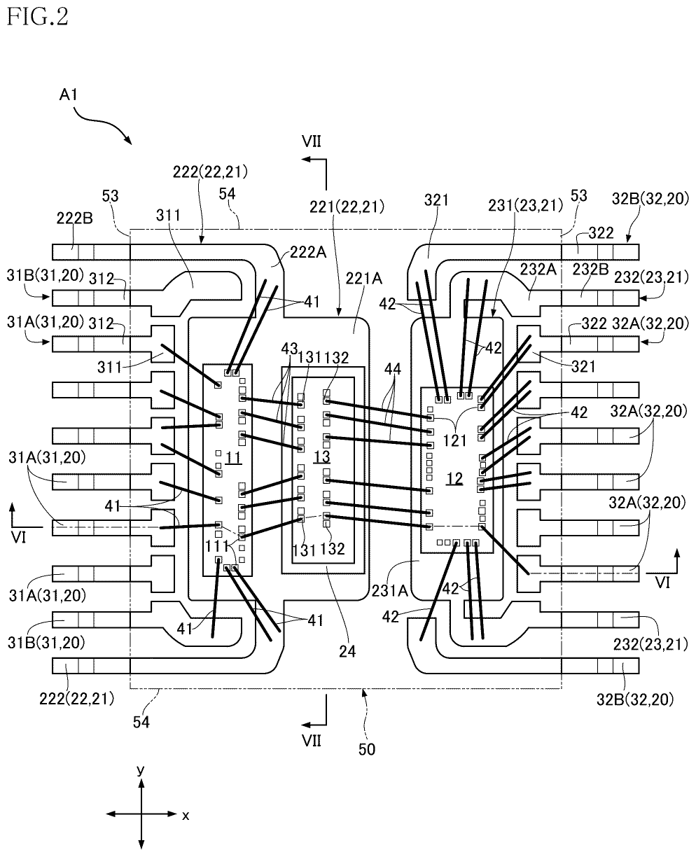

The semiconductor device A1 may be surface-mounted on a circuit board of an inverter device used in, for example, an electric vehicle or a hybrid vehicle. The package type of the semiconductor device A1 is SOP (Small Outline Package). According to the present disclosure, the package type of the semiconductor device A1 is not limited to SOP. In FIG. 2, for case of understanding, the sealing resin 50 is depicted as being transparent and indicated by imaginary lines (double dotted lines).

In the following description about the semiconductor device A1, the thickness direction of the first semiconductor element 11, the second semiconductor element 12, or the insulating element 13 is referred to as the “thickness direction z.” One direction perpendicular to the thickness direction z is called the “first direction x.” The direction perpendicular to both the thickness direction z and the first direction x is called the “second direction y.”

First Semiconductor Element 11, Second Semiconductor Element 12, Insulating Element 13:

The first semiconductor element 11, the second semiconductor element 12, and the insulating element 13 are core elements for performing the desired functions of the semiconductor device A1. In the semiconductor device A1, the first semiconductor element 11, the second semiconductor element 12, and the insulating element 13 are composed as individual or separate elements. In the first direction x, the insulating element 13 is disposed between the first semiconductor element 11 and the second semiconductor element 12. As viewed in the thickness direction z, the first semiconductor element 11, the second semiconductor element 12, and the insulating element 13 are rectangular in shape having relatively long sides extending in the second direction y. The semiconductor device of the present disclosure may not necessarily include such first and second semiconductor elements 11, 12.

The first semiconductor element 11 is a controller (control element) for a gate driver that drives switching elements such as IGBTs (Insulated Gate Bipolar Transistors) and MOSFETs (Metal-Oxide-Semiconductor Field-Effect Transistors). The first semiconductor element 11 includes a circuit that converts control signals inputted from an external ECU (Electronic Control Unit) into PWM (Pulse Width Modulation) control signals, and a transmitter circuit for transmitting the PWM control signals to the second semiconductor element 12, and a receiver circuit for receiving electrical signals from the second semiconductor element 12.

The second semiconductor element 12 is a gate driver (driving element) for driving switching elements, for example. The second semiconductor element 12 includes a receiver circuit for receiving PWM control signals, and a circuit for driving the switching elements based on the PWM control signal, and a transmitter circuit for transmitting electrical signals to the first semiconductor element 11. The electrical signal may be an output signal from a temperature sensor located near a motor.

The insulating element 13 transmits PWM control signals and other electrical signals in an insulated state. In the semiconductor device A1, the insulating element 13 is of an inductive type. An example of inductive insulating element 13 is an isolation transformer. An isolation transformer may include two inductively coupled inductors (coils) so as to transmit electrical signals in an insulated state. The insulating element 13 may include a substrate made of silicon. The two inductors, made of e.g., copper (Cu), are formed on the substrate. These inductors include a transmitter-side inductor and a receiver-side inductor, both of which are stacked along the thickness direction z. A dielectric layer made of silicon dioxide (SiO₂) or the like is disposed between the transmitter-side inductor and the receiver-side inductor so that the dielectric layer electrically insulates the transmitter-side inductor and the receiver-side inductor from each other. In another example, the insulating element 13 may be of a capacitive type. An example of capacitive-type insulating element 13 is a capacitor.

In the semiconductor device A1, the voltage applied to the first semiconductor element 11 and the voltage applied to the second semiconductor element 12 are different values. Thus, a potential difference is generated between the first semiconductor element 11 and the second semiconductor element 12. Further, in the semiconductor device A1, the power supply voltage supplied to the second semiconductor element 12 is higher than the power supply voltage supplied to the first semiconductor element 11.

In the semiconductor device A1, use is made of a first circuit including the first semiconductor element 11 as a constituting component and a second circuit including the second semiconductor element 12 as a constituting component, where the two circuits are insulated from each other by the insulating element 13. The insulating element 13 is electrically connected to the first circuit and the second circuit, respectively. The components of the first circuit include, in addition to the first semiconductor element 11, a first die pad 22 described below, a plurality of first terminals 31, a plurality of first wires 41, and a plurality of third wires 43. The components of the second circuit include, in addition to the second semiconductor element 12, a second die pad 23 described below, a plurality of second terminals 32, a plurality of second wires 42, and a plurality of fourth wires 44. The potentials of the first circuit and the second circuit are mutually different. In the semiconductor device A1, the potential of the second circuit is higher than that of the first circuit. The insulating element 13 relays signals to be transmitted between the first circuit and the second circuit. In an inverter device for electric vehicles or hybrid vehicles, the voltage applied to the first semiconductor element 11 may be approximately OV, while the voltage applied to the second semiconductor element 12 may be approximately 1 kV. In an insulation compliance testing for the semiconductor device A1, a voltage of approximately 10 kV, for example, may be applied to the second semiconductor element 12.

As shown in FIGS. 2 and 6, the first semiconductor element 11 has a plurality of first electrodes 111. The first electrodes 111 are provided on the upper surface of the first semiconductor element 11 (the surface facing in the same direction as the first mounting surface 221A of the first pad portion 221 of the first die pad 22 described later). The composition of the first electrodes 111 includes, for example, aluminum (A1). The first electrodes 111 are electrically connected to the circuit formed in the first semiconductor element 11.

As shown in FIGS. 2 and 6, the second semiconductor element 12 has a plurality of second electrodes 121. The second electrodes 121 are provided on the upper surface of the second semiconductor element 12 (the surface facing the same direction as the second mounting surface 231A of the second pad portion 231 of the second die pad 23 described later). The composition of the second electrodes 121 includes, for example, aluminum. The second electrodes 121 are electrically connected to the circuit formed in the second semiconductor element 12.

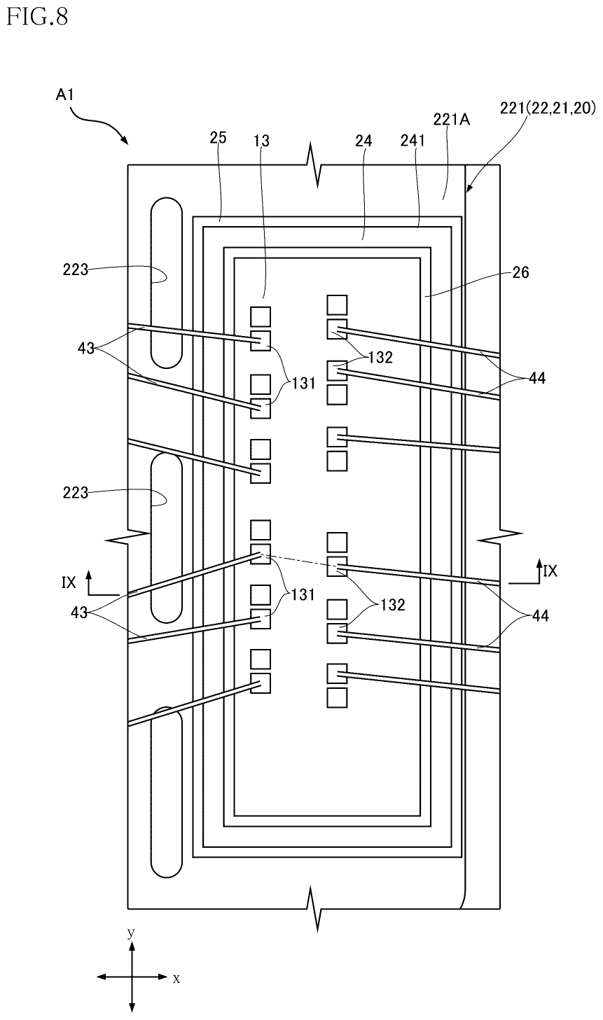

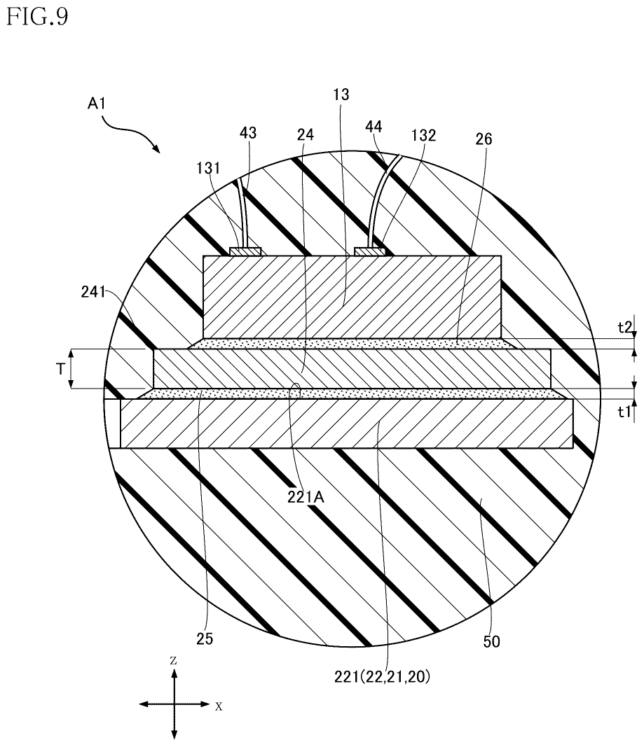

As shown in FIGS. 2 and 6, the insulating element 13 is disposed between the first semiconductor element 11 and the second semiconductor element 12 in the first direction x. As shown in FIGS. 8 and 9, the insulating element 13 has a plurality of first relay electrodes 131 and a plurality of second relay electrodes 132. The first relay electrodes 131 and the second relay electrodes 132 are provided on the upper surface of the insulating element 13 (which faces the same direction as the first mounting surface 221A mentioned above). The first relay electrodes 131 are arranged along the second direction y and are positioned closer to the first semiconductor element 11 than to the second semiconductor element 12 in the first direction x. The second relay electrodes 132 are arranged along the second direction y and are positioned closer to the second semiconductor element 12 than to the first semiconductor element 11 in the first direction x.

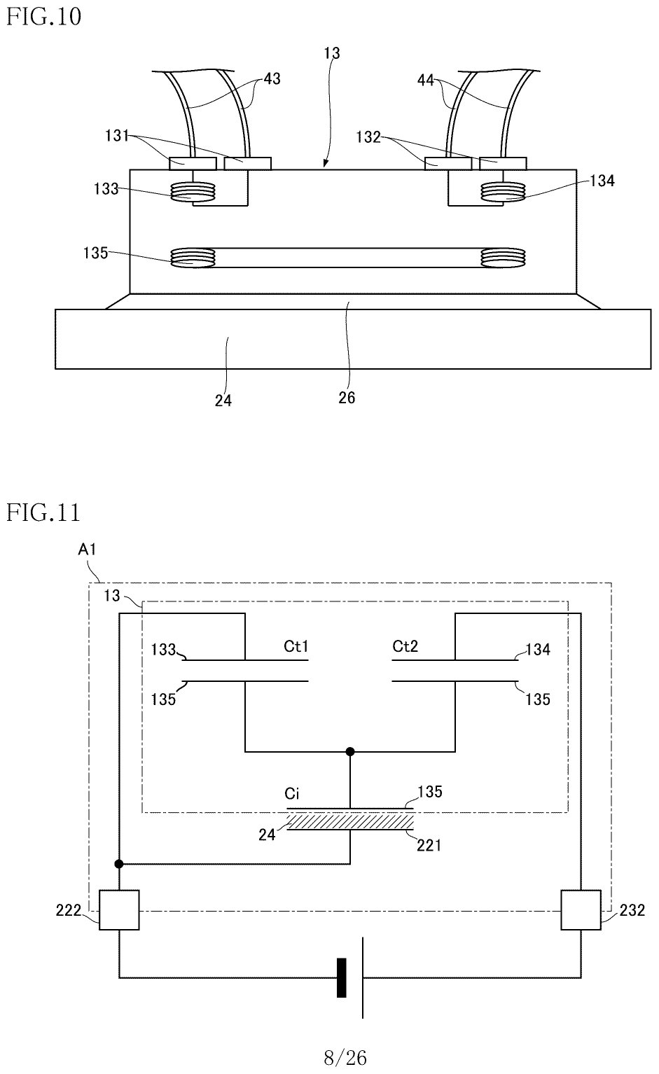

As shown in FIG. 10, the insulating element 13 further comprises a first transceiver 133, a second transceiver 134, and an interfacing member 135. The first transceiver 133, the second transceiver 134, and the interfacing member 135 are constituted by inductors. The first transceiver 133 and the second transceiver 134 are spaced apart from each other in the first direction x. The first transceiver 133 is electrically connected to the first relay electrodes 131, and the first transceiver 133 is electrically connected to the first semiconductor element 11 via third wires 43. The second transceiver 134 is electrically connected to the second relay electrodes 132, and the second transceiver 134 is electrically connected to the second semiconductor element 12 via fourth wires 44.

As shown in FIG. 10, the interfacing member 135 is spaced apart from the first transceiver 133 and the second transceiver 134 in the thickness direction z. Between the interfacing member 135 and the first and second transceivers 133, 134, an insulating layer (not shown) is provided, which may be made of silicon dioxide, for example. The interfacing member 135 is configured to relay signals transmitted between the first transceiver 133 and the second transceiver 134. In the thickness direction z, the interfacing member 135 is closer to the insulating substrate 24 than are the first transceiver 133 and the second transceiver 134. The potential of the interfacing member 135 takes a value between the potential of the first transceiver 133 and the potential of the second transceiver 134.

### Conductive Members 20:

The conductive members 20 form a conduction path(s) for connecting the first semiconductor element 11, the insulating element 13 and the second semiconductor element 12 to the circuit board on which the semiconductor device A1 is mounted. The conductive members 20 are, for example, obtained from a common lead frame. The composition of the lead frame includes, for example, Cu (copper). The conductive members 20 include an element support (die pad) 21, a plurality of first terminals 31, and a plurality of second terminals 32. In the semiconductor device A1, the element support 21 includes a first die pad 22 and a second die pad 23.

### First Die Pad 22 and Second Die Pad 23:

The first die pad 22 and the second die pad 23 are spaced apart from each other in the first direction x, as shown in FIG. 1 and FIG. 2. In the semiconductor device A1, the first semiconductor element 11 and the insulating substrate 24 are bonded to the first die pad 22, and the second semiconductor element 12 is bonded to the second die pad 23. The voltage applied to the second die pad 23 is different from the voltage applied to the first die pad 22. In the semiconductor device A1, the voltage applied to the second die pad 23 is higher than the voltage applied to the first die pad 22.

As shown in FIG. 2, the first die pad 22 includes a first pad portion 221 and two first suspension leads 222. The first semiconductor element 11 is disposed on the first pad portion 221. As shown in FIGS. 6 and 7, the first pad portion 221 has a first mounting surface 221A facing in the thickness direction z. The first semiconductor element 11 is bonded to the first mounting surface 221A via a conductive bonding material (such as solder or metal paste). The first pad portion 221 is covered with the sealing resin 50. The thickness of the first pad portion 221 is, for example, not less than 150 μm and not more than 200 μm.

The configurations of the first pad portion 221 are not limitative. For example, the first pad portion 221 may have a through-hole extending between the first semiconductor element 11 and the insulating substrate 24 (insulating element 13). In the manufacture of the semiconductor device A1, by passing the resin material for forming the sealing resin 50 through the through-hole, it is possible to suppress incomplete filling of the resin.

As shown in FIG. 2, the two first suspension leads 222 are connected to the respective ends of the first pad portion 221 in the second direction y. The two first suspension leads 222 each have a covered portion 222A and an exposed portion 222B. The covered portion 222A is connected to the first pad portion 221 and covered by the sealing resin 50. The covered portion 222A includes a section extending in the first direction x. The exposed portion 222B is connected to the covered portion 222A and exposed from the sealing resin 50. As viewed in the thickness direction z, the exposed portion 222B extends along the first direction x. As shown in FIG. 3, as viewed in the second direction y, the exposed portion 222B is bent. The surface of the exposed portion 222B may be plated with, for example, Sn (tin).

As shown in FIG. 2, the second die pad 23 includes a second pad portion 231 and two second suspension leads 232. The second semiconductor element 12 is disposed on the second pad portion 231. As shown in FIG. 6, the second pad portion 231 has a second mounting surface 231A facing in the thickness direction z. The second semiconductor element 12 is bonded to the second mounting surface 231A via a conductive bonding material (such as solder or metal paste). The second pad portion 231 is covered with the sealing resin 50. The thickness of the second pad portion 231 is, for example, not less than 150 μm and not more than 200 μm. The surface area of the second pad portion 231 is smaller than the surface area of the first pad portion 221 of the first die pad 22. As viewed in the first direction x, the second pad portion 231 overlaps with the first pad portion 221.

As shown in FIG. 2, the two second suspension leads 232 extend from the respective ends of the second pad portion 231 in the second direction y. The two second suspension leads 232 each have a covered portion 232A and an exposed portion 232B. The covered portion 232A is connected to the second pad portion 231 and covered by the sealing resin 50. The covered portion 232A includes a section extending in the first direction x. The exposed portion 232B is connected to the covered portion 232A and exposed from the sealing resin 50. As viewed in the thickness direction z, the exposed portion 232B extends along the first direction x. Referring to FIG. 3, the exposed portion 232B is bent, as viewed in the second direction y. The surface of the exposed portion 232B may be plated with, for example, tin.

### First Terminals 31:

The first terminals 31 are located on one side of the first direction x, as shown in FIG. 1 and FIG. 2. Specifically, the first terminals 31 are located opposite, with respect to the first pad portion 221 of the first die pad 22, from the second pad portion 231 of the second die pad 23 in the first direction x. The first terminals 31 are arranged along the second direction y. One or more of the first terminals 31 are electrically connected to the first semiconductor element 11 via first wires 41. The first terminals 31 include first intermediate terminals 31A and two first lateral terminals 31B. The two first lateral terminals 31B are located on the respective sides of the first intermediate terminals 31A in the second direction y. In the second direction y, each first lateral terminal 31B is located between a corresponding one of the two first suspension leads 222 of the first die pad 22 and the first intermediate terminal 31A closest to the corresponding first suspension lead 222.

As shown in FIGS. 2 and 6, the first terminals 31 each include a covered portion 311 and an exposed portion 312. The covered portion 311 is covered with the sealing resin 50. The dimension of the covered portion 311 of each first lateral terminal 31B in the first direction x is great than the dimension of the covered portion 311 of each first intermediate terminal 31A in the first direction x.

As shown in FIGS. 2 and 6, in each first terminal 31, the exposed portion 312 is connected to the covered portion 311 and exposed from the sealing resin 50. As viewed in the thickness direction z, the exposed portion 312 extends along the first direction x. As viewed in the second direction y, the exposed portion 312 is bent. The shape of the exposed portion 312 is the same as the shape of the exposed portion 222B of each first suspension lead 222 of the first die pad 22. The surface of the exposed portion 312 may be plated with, for example, Sn (tin).

### Second Terminal 32:

The second terminals 32 are located on the opposite side of the first direction x, as shown in FIGS. 1 and 2. Specifically, the second terminals 32 are located opposite, with respect to the first pad portion 221 of the first die pad 22, from the first terminals 31 in the first direction x. The second terminals 32 are arranged along the second direction y. One or more of the second terminals 32 are electrically connected to the second semiconductor element 12 via second wires 42. The second terminals 32 include a plurality of second intermediate terminals 32A and two second lateral terminals 32B. The two second lateral terminals 32B are located on both sides of the second intermediate terminals 32A in the second direction y. In the second direction y, each of the two second suspension leads 232 of the second die pad 23 is located between a corresponding one of the two second lateral terminals 32B and the second intermediate terminal 32A closest to the corresponding second lateral terminal 32B.

As shown in FIGS. 2 and 6, the second terminals 32 each have a covered portion 321 and an exposed portion 322. The covered portion 321 is covered with the sealing resin 50. The dimension of the covered portion 321 of each second lateral terminal 32B in the first direction x is great than the dimension of the covered portion 321 of each second intermediate terminal 32A in the first direction x.

As shown in FIGS. 2 and 6, in each second terminal portion, the exposed portion 322 is connected to the covered portion 321 and is exposed from the sealing resin 50. As viewed in the thickness direction z, the exposed portion 322 extends along the first direction x. As shown in FIG. 3, as viewed in the second direction y, the exposed portion 322 is bent. The shape of the exposed portion 322 is the same as the shape of the exposed portion 232B of each second suspension lead 232 of the second die pad 23. The surface of the exposed portion 322 may be plated with, for example, tin.

### Insulating Substrate 24:

The insulating substrate 24 is bonded to the element support 21 as shown in FIGS. 2, 6, and 7. As viewed in the thickness direction z, the insulating substrate 24 is located inward of the periphery of the element support 21. In the semiconductor device A1, the insulating substrate 24 is bonded to the first pad portion 221 of the first die pad 22. The insulating substrate 24 may be made of ceramics such as alumina Al₂O₃ (alumina), AlN (aluminum nitride), and the like. As viewed in the thickness direction z, the insulating substrate 24 is rectangular. The insulating element 13 is bonded to the insulating substrate 24. The insulating substrate 24 is disposed between the element support 21 (the first pad portion 221 of the first die pad 22) and the insulating element 13. The thickness T of the insulating substrate 24 is not limitative, and may be, for example, not less than 50 μm and not more than 300 μm.

The first bonding layer 25 is disposed between the element support 21 (the first pad portion 221 of the first die pad 22) and the insulating substrate 24, as shown in FIG. 9. In the semiconductor device A1, the insulating substrate 24 is bonded to the first mounting surface 221A of the first pad portion 221 via the first bonding layer 25. The thickness t1 of the first bonding layer 25 is, for example, smaller than the thickness T of the insulating substrate 24. The thickness t1 of the first bonding layer 25 is not limitative and is, for example, not less than 5 μm and not more than 50 μm. In the semiconductor device A1, as shown in FIGS. 8 and 9, as viewed in the thickness direction z, the first bonding layer 25 includes a portion extending outward beyond the periphery 241 of the insulating substrate 24. The first bonding layer 25 is electrically insulating. The first bonding layer 25 is, for example, made of a material including epoxy resin.

The second bonding layer 26 is disposed between the insulating substrate 24 and the insulating element 13, as shown in FIG. 9. The insulating element 13 is bonded to the insulating substrate 24 via the second bonding layer 26. The thickness t2 of the second bonding layer 26 is smaller than the thickness T of the insulating substrate 24, for example. The thickness t2 of the second bonding layer 26 is not limitative, and is, for example, not less than 5 μm and not more than 50 μm. In the semiconductor device A1, as shown in FIG. 8, as viewed in the thickness direction z, the surface area of the second bonding layer 26 is smaller than the surface area of the first bonding layer 25. The second bonding layer 26 is electrically insulating. The second bonding layer 26 is, for example, made of a material containing epoxy resin.

### First Wires 41, Second Wires 42, Third Wires 43, Fourth Wires 44:

The first wires 41, the second wires 42, the third wires 43, and the fourth wires 44 are configured to, together with the conductive members 20, constitute conduction paths for enabling the first semiconductor element 11, the second semiconductor element 12, and the insulating element 13 to perform their respective functions.

The first wires 41 are connected to first electrodes 111 of the first semiconductor element 11 and to the covered portions 311 of first terminals 31, as shown in FIGS. 2 and 6. As a result, one or more of the first terminals 31 are electrically connected to the first semiconductor element 11. Further, one or more of the first wires 41 are connected to first electrodes 111 and to the covered portions 222A of the two first suspension leads 222 of the first die pad 22. As a result, one or more of the two first suspension leads 222 are electrically connected to the first semiconductor element 11. As a result, one or more of the two first suspension leads 222 serve as a ground terminal of the first semiconductor element 11. The composition of the first wires 41 includes Au (gold). The composition of the first wires 41 may include Cu (copper).

The second wires 42 are connected to second electrodes 121 of the second semiconductor element 12 and to the covered portions 321 of second terminals 32, as shown in FIGS. 2 and 6. As a result, one or more of the second terminals 32 are electrically connected to the second semiconductor element 12. Further, one or more of the second wires 42 are connected to second electrodes 121 and to one or more of the covered portions 232A of the two second suspension leads 232 of the second die pad 23. As a result, one or more of the two second suspension leads 232 are electrically connected to the second semiconductor element 12. As a result, one or more of the two second suspension leads 232 serve as a ground terminal of the second semiconductor element 12. The composition of the second wires 42 includes Au (gold). The composition of the second wires 42 may include Cu (copper).

The third wires 43 are connected to first relay electrodes 131 of the insulating element 13 and to first electrodes 111 of the first semiconductor element 11, as shown in FIGS. 2 and 6. As a result, the first semiconductor element 11 and the insulating element 13 are electrically connected to each other. The third wires 43 are arranged in the second direction y. The composition of the third wires 43 includes Au (gold).

The fourth wires 44 are connected to second relay electrodes 132 of the insulating element 13 and to second electrodes 121 of the second semiconductor element 12, as shown in FIGS. 2 and 6. Thus, the second semiconductor element 12 and the insulating element 13 are electrically connected to each other. The fourth wires 44 are arranged in the second direction y. In the semiconductor device A1, as viewed in the thickness direction z, the fourth wires 44 bridge between the first pad portion 221 of the first die pad 22 and the second pad portion 231 of the second die pad 23. The composition of the fourth wires 44 includes Au (gold).

### Scaling Resin 50:

As shown in FIG. 1, the sealing resin 50 covers the first semiconductor element 11, the second semiconductor element 12, and the insulating element 13, while also covering at least a part of each conductive member 20. Further, the sealing resin 50 covers the first wires 41, the second wires 42, the third wires 43, and the fourth wires 44. The scaling resin 50 is electrically insulating. The scaling resin 50 is made of a material including, for example, an epoxy resin. As viewed in the thickness direction z, the sealing resin 50 is rectangular.

As shown in FIGS. 3 to 5, the sealing resin 50 has a top surface 51, a bottom surface 52, a pair of first side surfaces 53, and a pair of second side surfaces 54.

As shown in FIGS. 3 to 5, the top surface 51 and the bottom surface 52 are spaced apart from each other in the thickness direction z. The top surface 51 and the bottom surface 52 face away from each other in the thickness direction z. The top surface 51 and the bottom surface 52 are each flat (or substantially flat).

As shown in FIGS. 3 to 5, the first side surfaces 53 are connected to the top surface 51 and the bottom surface 52, and are spaced apart from each other in the first direction x. The pair of the first side surfaces 53 includes one first side surface 53 located on one side of the first direction x. From this first side surface 53, the exposed portions 222B of the two first suspension leads 222 and the exposed portions 312 of the first terminals 31 are exposed. The first side surfaces 53 includes the other first side surface 53 located on the other or opposite side of the first direction x. From this first side surface 53, the exposed portions 222B of the two second suspension leads 232 and the exposed portions 322 of the second terminal portions 32 are exposed.

As shown in FIGS. 3 to 5, each first side surface 53 includes a first upper portion 531, a first lower portion 532, and a first middle portion 533. The first upper portion 531 is connected to the top surface 51 on one side in the thickness direction z and is connected to the first middle portion 533 on the other side in the thickness direction z. The first upper portion 531 is inclined relative to the top surface 51. The first lower portion 532 is connected to the bottom surface 52 on one side in the thickness direction z and to the first middle portion 533 on the other side in the thickness direction z. The first lower portion 532 is inclined relative to the bottom surface 52. The first middle portion 533 is connected to the first upper portion 531 on one side in the thickness direction z and to the first lower portion 532 on the other side in the thickness direction z. The in-plane directions of the first middle portion 533 include the thickness direction z and the second direction y. As viewed in the thickness direction z, the first middle portion 533 is located outward of both the top surface 51 and the bottom surface 52. The first middle portion 533 of one of the two first side surfaces 53 is the portion from which the exposed portions 222B of the first suspension leads 222 of the first die pad 22 and the exposed portions 312 of the first terminals 31 protrude outwards. Likewise, the first middle portion 533 of the other of the two first side surfaces 53 is the portion from which the exposed portions 222B of the two second suspension leads 232 of the second die pad 23 and the exposed portions 322 of the second terminal portions 32 protrude outwards.

As shown in FIGS. 3 to 5, the two second side surfaces 54 are connected to the top surface 51 and the bottom surface 52, and are spaced apart from each other in the second direction y. As shown in FIG. 1, the first die pad 22, the second die pad 23, the first terminals 31, and the second terminals 32 are spaced apart from the second side surfaces 54.

As shown in FIGS. 3 to 5, each second side surface 54 includes a second upper portion 541, a second lower portion 542, and a second middle portion 543. The second upper portion 541 is connected to the top surface 51 on one side in the thickness direction z and to the second middle portion 543 on the other side in the thickness direction z. The second upper portion 541 is inclined relative to the top surface 51. The second lower portion 542 is connected to the bottom surface 52 on one side in the thickness direction z and to the second middle portion 543 on the other side in the thickness direction z. The second lower portion 542 is inclined relative to the bottom surface 52. The second middle portion 543 is connected to the second upper portion 541 on one side in the thickness direction z and to the second lower portion 542 on the other side in the thickness direction z. The in-plane directions of the second middle portion 543 include the thickness direction z and the second direction y. As viewed in the thickness direction z, the second middle portion 543 is located outward of both the top surface 51 and the bottom surface 52.

Generally, in a motor driver circuit of an inverter device, a half-bridge circuit is configured, which includes low-side (low potential side) switching elements and high-side (high potential side) switching elements. In the following example, the switching elements are, without limitation, MOSFETs. In the low-side switching elements, the reference potential of the sources of the switching elements and the reference potential of the gate driver for driving the switching elements are both ground potential. In the high-side switching elements, the reference potential of the sources of the switching elements and the reference potential of the gate driver for driving the switching elements correspond to the potential at the output node of the half-bridge circuit. The potential at the output node changes depending on the operation of the high-side and the low-side switching elements. Accordingly, the reference potential of the gate driver for driving the high-side switching elements will change. When the high-side switching elements are on, the reference potential of the gate driver is equivalent to the voltage applied to the drains of the high-side switching elements. In the semiconductor device A1, the ground of the first semiconductor element 11 and the ground of the second semiconductor element 12 are separated from each other. Thus, when the semiconductor device A1 is used as a gate driver for driving the high-side switching elements, a voltage equal to the voltage applied to the drains of the high-side switching elements is transiently applied to the ground of the second semiconductor element 12.

Advantages of the semiconductor device A1 will be described below.

According to the present embodiment, the semiconductor device A1 comprises the conductive members 20 including the element support 21, the first and the second semiconductor elements 11, 12 disposed on the element support 21, and the insulating element 13 for electrically insulating the first semiconductor element 11 and the second semiconductor element 12 from each other. The semiconductor device A1 further comprises the insulating substrate 24 disposed between the element support 21 and the insulating element 13 and bonded to the element support 21. The insulating element 13 is bonded to the insulating substrate 24. Dielectric breakdown of the insulating element 13 occurs when charged carriers move from the element support 21 to the insulating element 13. With the configurations of the present disclosure, the insulating substrate 24 can prevent the charged carriers from moving from the upper surface of the element support 21 (the first mounting surface 221A of the first pad portion 221) to the lower surface of the insulating element 13, which is opposite to the upper surface of the element support 21. Accordingly, the insulating element 13 is less susceptible to dielectric breakdown. As a result, the semiconductor device A1 is advantageous to improving the dielectric strength between the insulating element 13 and the element support 21 with the semiconductor elements (first/second semiconductor element 11, 12) mounted thereon.

FIG. 11 is a circuit diagram for illustrating the semiconductor device A1. In this Figure, the first semiconductor element 11 and the second semiconductor element 12 are omitted. The insulating element 13 has a capacitance Ct1 between the first transceiver 133 and the interfacing member 135, and a capacitance Ct2 between the second transceiver 134 and the interfacing member 135. The interfacing member 135 faces the first pad portion 221 through the insulating substrate 24, whereby a capacitance Ci exists between the interfacing member 135 and the first pad portion 221. The capacitances Ct1 and Ci are connected in parallel, as show in the Figure, while the capacitances Ct1 and Ci are connected in series with the capacitance Ct2. In this situation, if the capacitances Ct1 and Ct2 are the same value, the following inconvenience may occur. Duc to the presence of capacitance Ci, the potential of the interfacing member 135 shifts toward the potential of the first transceiver 133 from the midpoint potential between the potential of the first transceiver 133 and the potential the second transceiver 134. Thus, the potential difference between the second transceiver 134 and the interfacing member 135 is greater than the potential difference between the first transceiver 133 and the interfacing member 135. In this case, even if the dielectric strengths between the first transceiver 133 and the interfacing member 135, and between the second transceiver 134 and the interfacing member 135 are greater than half of the voltage applied to the first transceiver 133, there may be a risk of dielectric breakdown occurring between the second transceiver 134 and the interfacing member 135. To avoid such dielectric breakdown, it may be preferable to make the capacitance Ct1 smaller than the capacitance Ct2.

When the thickness T of the insulating substrate 24 is not less than 50 μm and not more than 300 μm, the capacitance Ci becomes smaller, thereby reducing the risk of dielectric breakdown between the second transceiver 134 and the interfacing member 135, while suppressing an increase in the size of the semiconductor device A1 in the thickness direction z. Preferably, the thickness t1 is not less than 5 μm and not more than 50 μm, and the thickness t2 is not less than 5 μm and not more than 50 μm. This configuration can further reduce the capacitance Ci, while suppressing an increase in the size of the semiconductor device A1 in the thickness direction z.

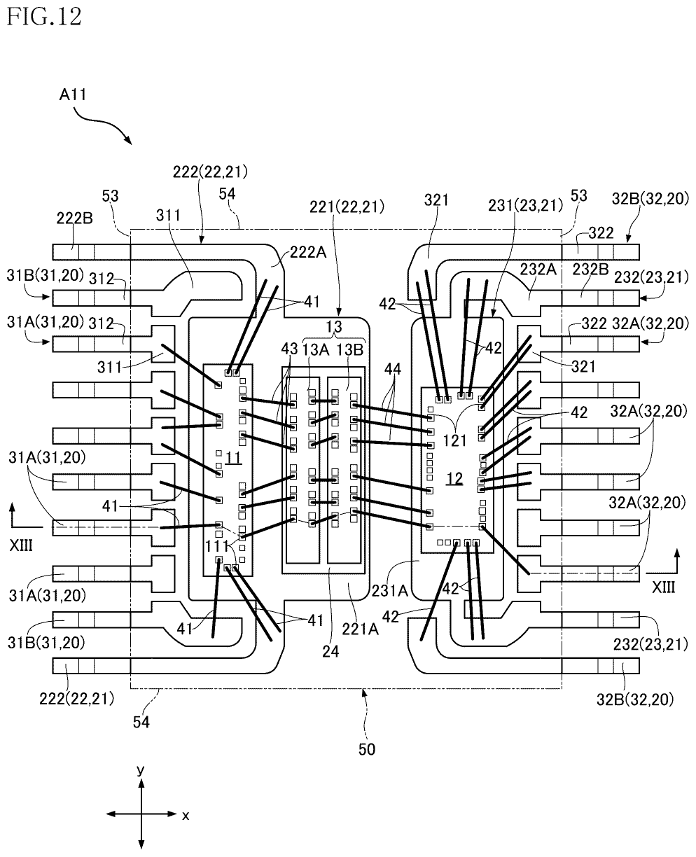

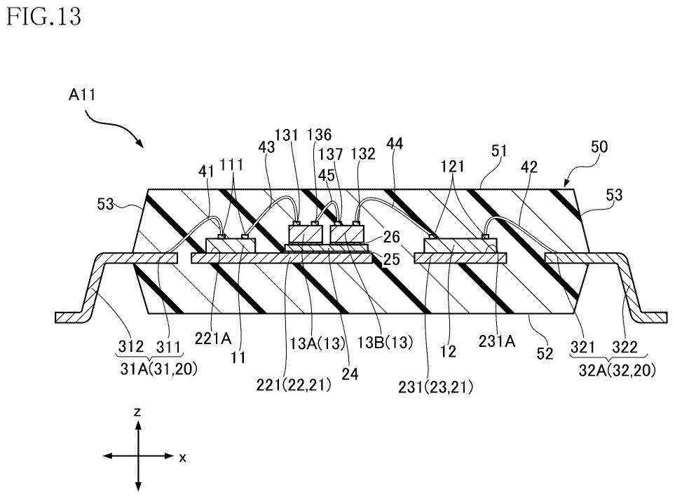

FIGS. 12 to 31 show variations and other embodiments of the present disclosure. In these figures, elements that are the same or similar to those in the above embodiment are indicated by the same reference numerals as in the above embodiment. The configurations of respective parts of the variations and the embodiments may be combined as appropriate and without causing technical incompatibles.

### First Embodiment—First Variation

FIGS. 12 to 16 show a first variation of the semiconductor device A1. In this variation, the semiconductor device A11 has an insulating element 13 whose configuration differs from that of the semiconductor device A1 described above. The semiconductor device A11 further comprises a plurality of fifth wires 45.

As shown in FIGS. 12 to 15, the insulating element 13 includes a first insulating element 13A and a second insulating element 13B spaced apart from each other. In the semiconductor device A11, the first insulating element 13A and the second insulating element 13B are spaced apart in the first direction x such that the first insulating element 13A is closer to the first semiconductor element 11 than is the second insulating element 13B.

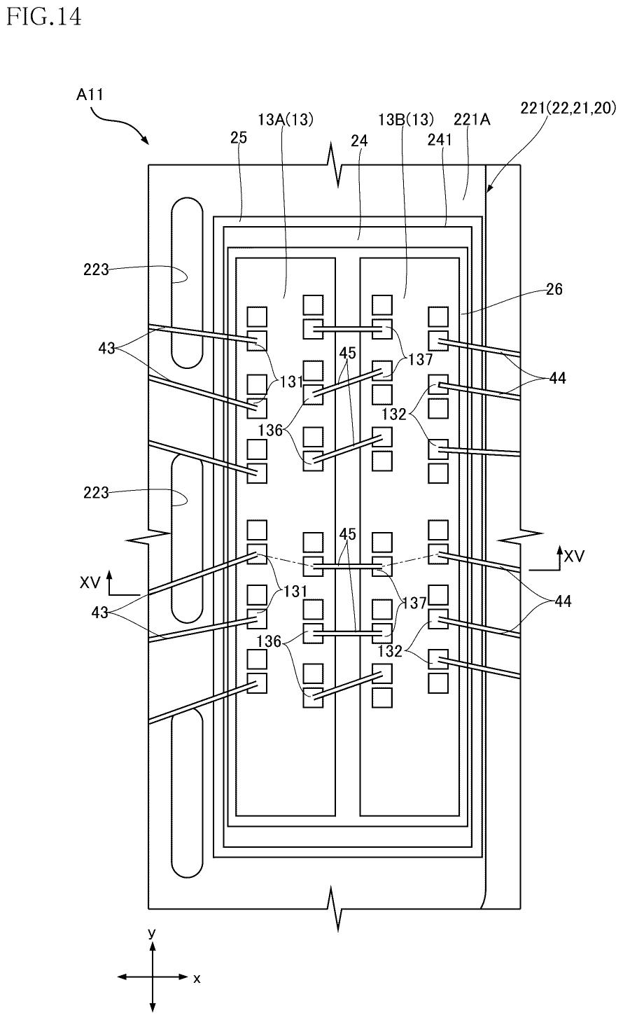

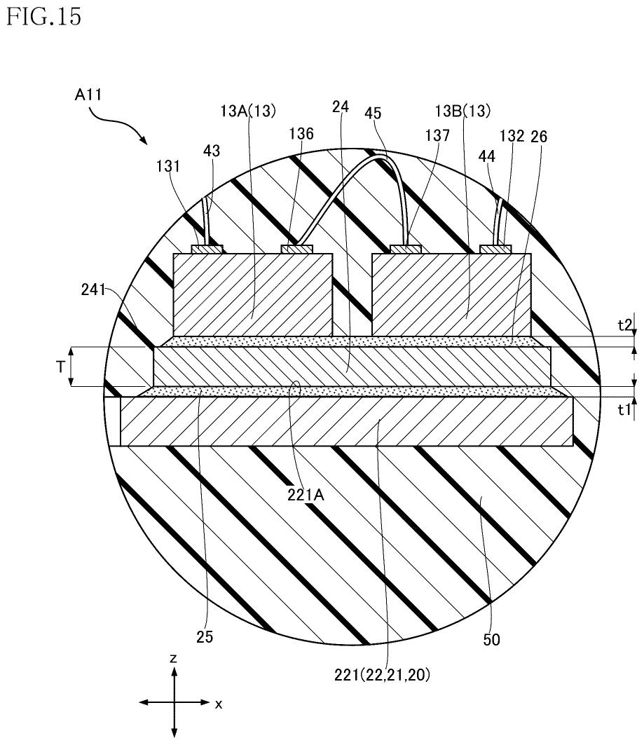

The first insulating element 13A and the second insulating element 13B are bonded to the insulating substrate 24 via a second bonding layer 26. As shown in FIGS. 14 and 15, in the semiconductor device A11, the second bonding layer 26 is formed as a single integral layer. Alternatively, the second bonding layer 26 may include mutually separated regions for separately supporting the first insulating element 13A and the second insulating element 13B, respectively.

In the semiconductor device A11, the insulating substrate 24 is bonded to the first mounting surface 221A of the first pad portion 221 of the first die pad 22 via the first bonding layer 25. Alternatively, as in the above-discussed semiconductor device A1, the insulating substrate 24 may be bonded to the second mounting surface 231A of the second pad portion 231 of the second die pad 23.

As shown in FIG. 14, the first insulating element 13A is provided with first relay electrodes 131 and third relay electrodes 136. The third wires 43 are bonded to first relay electrodes 131 and first electrodes 111 of the first semiconductor element 11. Thus, the first relay electrodes 131 are electrically connected to the first semiconductor element 11.

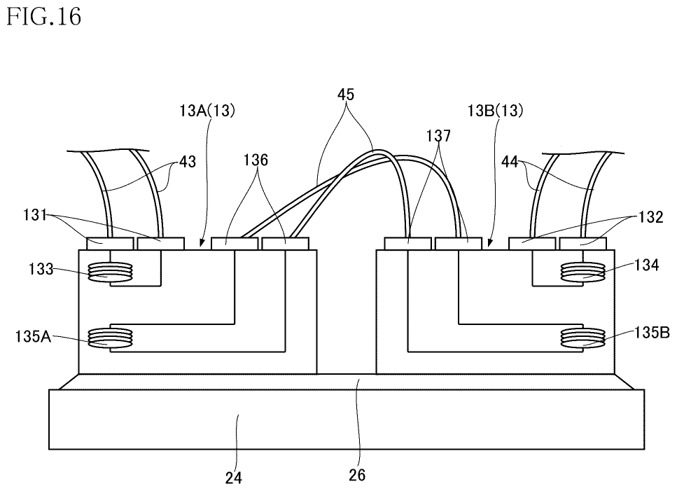

As shown in FIG. 16, the first insulating element 13A includes a first transceiver 133 and a first interfacing member 135A. In the semiconductor device A11, the first transceiver 133 and the first interfacing member 135A are inductors. The first transceiver 133 and the first interfacing member 135A are spaced apart from each other in the thickness direction z. In the first insulating element 13A, a dielectric layer (not shown) composed of silicon dioxide or the like is disposed between the first transceiver 133 and the first interfacing member 135A. The first transceiver 133 is electrically connected to first relay electrodes 131. Thus, the first transceiver 133 is electrically connected to the first semiconductor element 11. The first interfacing member 135A transmits and receives signals with the first transceiver 133. The first interfacing member 135A is electrically connected to third relay electrodes 136. In the thickness direction z, the first interfacing member 135A is located closer to the insulating substrate 24 than is the first transceiver 133.

As shown in FIG. 14, the second insulating element 13B is provided with fourth relay electrodes 137 and second relay electrodes 132. The fourth wires 44 are bonded to second relay electrodes 132 and to second electrodes 121 of the second semiconductor element 12. Thus, the second relay electrodes 132 are electrically connected to the second semiconductor element 12.

As shown in FIG. 16, the second insulating element 13B includes a second interfacing member 135B and a second transceiver 134. In the semiconductor device A11, the second interfacing member 135B and the second transceiver 134 are inductors. The second interfacing member 135B and the second transceiver 134 are spaced apart from each other in the thickness direction z. In the second insulating element 13B, a dielectric layer (not shown) composed of silicon dioxide or the like is disposed between the second interfacing member 135B and the second transceiver 134. The second transceiver 134 is electrically connected to second relay electrodes 132. Thus, the second transceiver 134 is electrically connected to the second semiconductor element 12. The second interfacing member 135B transmits and receives signals with the second transceiver 134. The second interfacing member 135B is electrically connected to fourth relay electrodes 137. In the thickness direction z, the second interfacing member 135B is located closer to the insulating substrate 24 than is the second transceiver 134.

As shown in FIGS. 14 and 15, fifth wires 45 are bonded to third relay electrodes 136 of the first insulating element 13A and to fourth relay electrodes 137 of the second insulating element 13B. The composition of the fifth wires 45 includes gold. Thus, the third relay electrodes 136 and the fourth relay electrodes 137 are electrically connected to each other. Further, the second interfacing member 135B of the second insulating element 13B is electrically connected to the first interfacing member 135A of the first insulating element 13A. Accordingly, the potential of the second interfacing member 135B is equal to the potential of the first interfacing member 135A. With these arrangements, the potential of the first interfacing member 135A and the second interfacing member 135B is between the potential of the first transceiver 133 of the first insulating element 13A and the potential of the second transceiver 134 of the second insulating element 13B.

The dielectric breakdown of the insulating element 13 can also be suppressed by this variation. As understood from this variation, the configurations of the insulating element 13 are not limitative. The first insulating element 13A and the second insulating element 13B may be a capacitive type.

### Second Embodiment

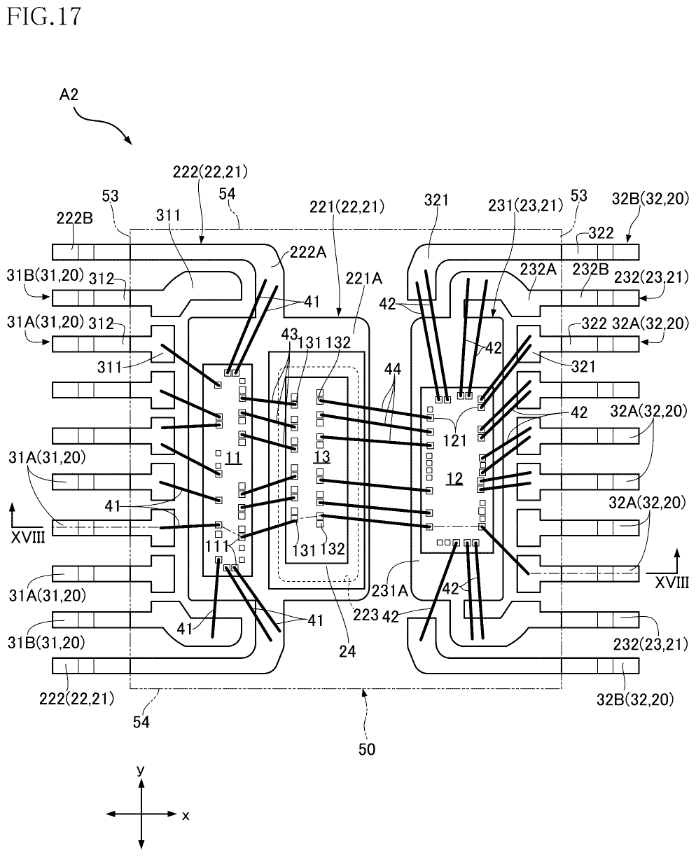

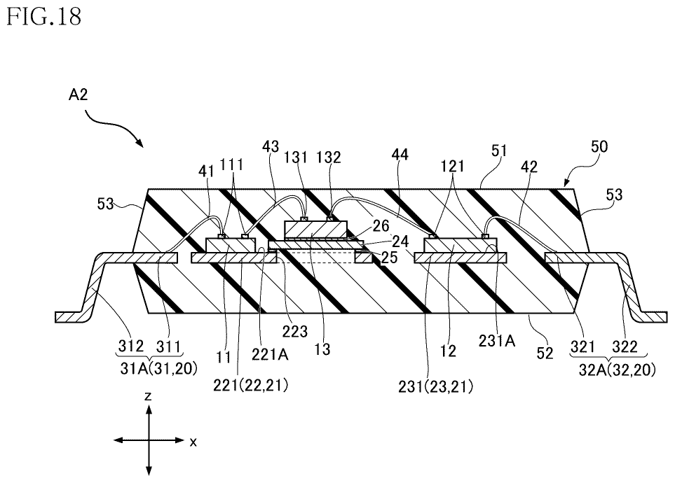

FIGS. 17 and 18 show a semiconductor device according to a second embodiment of the present disclosure. The semiconductor device A2 of the present embodiment has a first die pad 22 whose configuration differs from that of the embodiment described above.

In the present embodiment, the first die pad 22 has a first opening 223. The first opening 223 penetrates through the first die pad 22 in the thickness direction z so that it is open at its respective ends in the thickness direction. The number, shape, and size of the first opening(s) 223 are not limitative. It is possible to provide a single first opening 223 or multiple first openings 223. In the illustrated example, use is made of only one first opening 223. The shape of the first opening 223 is not limitative, and may be rectangular, polygonal, circular, elliptical, etc. In the illustrated example, the first opening 223 is rectangular (or substantially rectangular).

In the illustrated example, the first opening 223 overlaps with the insulating substrate 24 as viewed in the thickness direction z. The first opening 223 is blocked by the insulating substrate 24. The first opening 223 overlaps with the insulating element 13 as viewed in the thickness direction z. In the illustrated example, the first opening 223 overlaps with the entirety of the insulating element 13. In other words, the insulating element 13 as a whole is disposed or contained within the first opening 223 as viewed in the thickness direction z.

The present embodiment also enables the dielectric strength of the insulating element 13 to be increased. In the present embodiment, the overlapping area between the first die pad 22 and the interfacing member 135 is reduced due to the presence of the first opening 223 in the first die pad 22. As a result, capacitance Ci noted with reference to FIG. 11 can be reduced. As a result, the degree to which the potential of the interfacing member 135 shifts toward the potential of the first die pad 22 is mitigated, which is advantageous to suppressing dielectric breakdown of the insulating element 13.

### Second Embodiment—First Variation

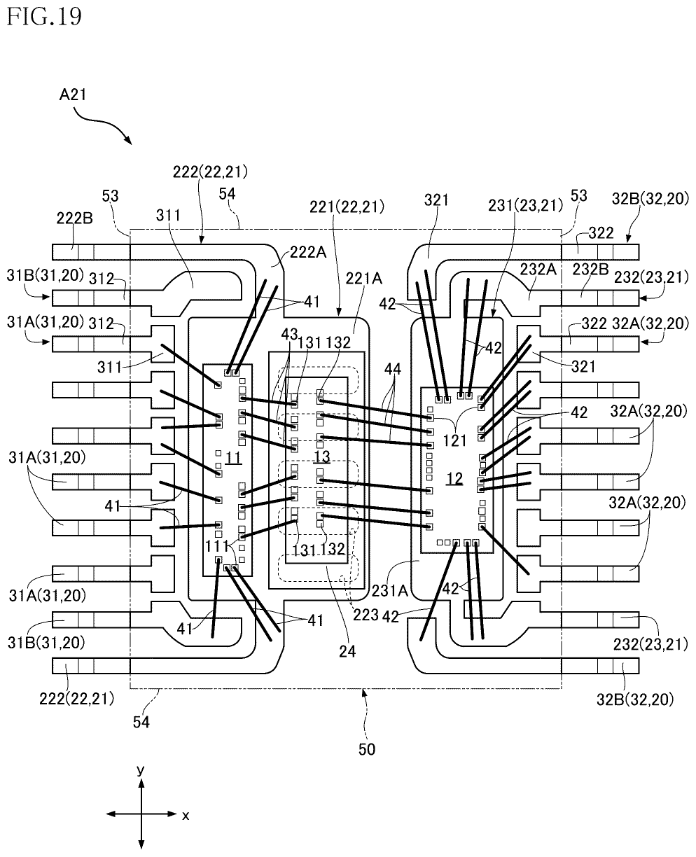

FIG. 19 shows a first variation of the semiconductor device A2. In the semiconductor device A21 of this variation, the first die pad 22 is formed with a plurality of first openings 223. The first openings 223 are spaced apart from each other in the second direction y. Each first opening 223 overlaps with a corresponding portion of the insulating element 13.

This variation also enables the dielectric strength of the insulating element 13 to be increased. As seen from this variation, the number, shape, and location of the first openings 223 are not limitative.

### Second Embodiment—Second Variation

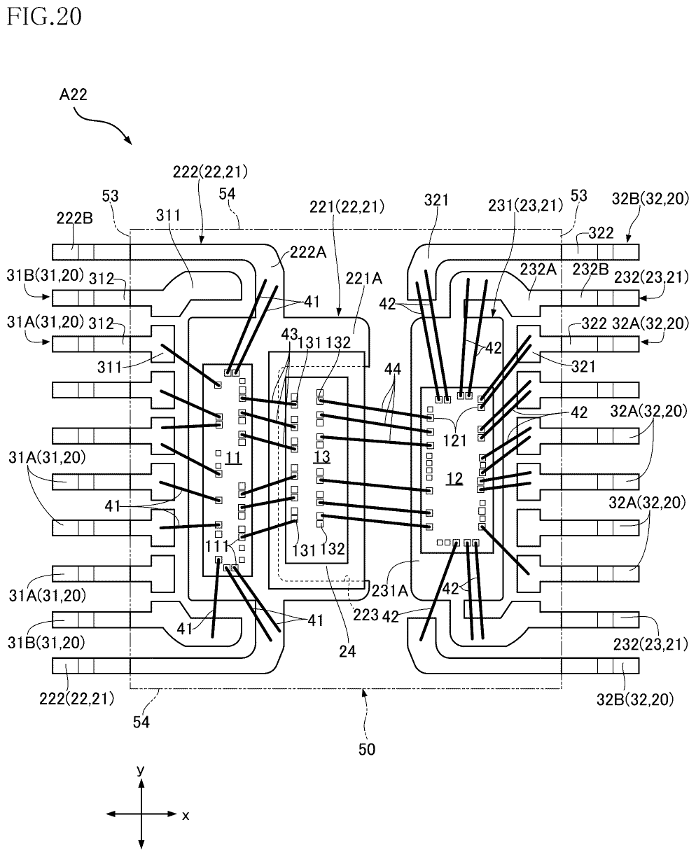

FIG. 20 shows a second variation of the semiconductor device A2. In the semiconductor device A22 of this variation, the first opening 223 is configured to open from the first die pad 22, as viewed in the thickness direction z. Specifically, the first opening 223 is opened on one side of the first die pad 22 in the first direction x. In the example shown in the figure, the insulating substrate 24 covers most of the first opening 223.

The dielectric strength of the insulating element 13 can also be increased by this variation. As seen from this variation, the first opening 223 may have an entirely closed periphery or a partially opened periphery as viewed in the thickness direction.

### Third Embodiment

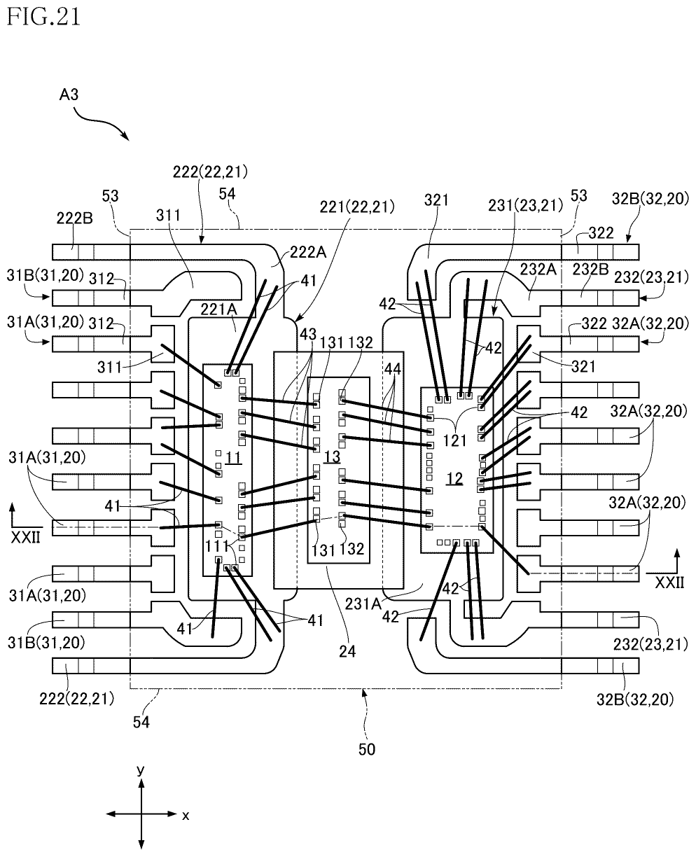

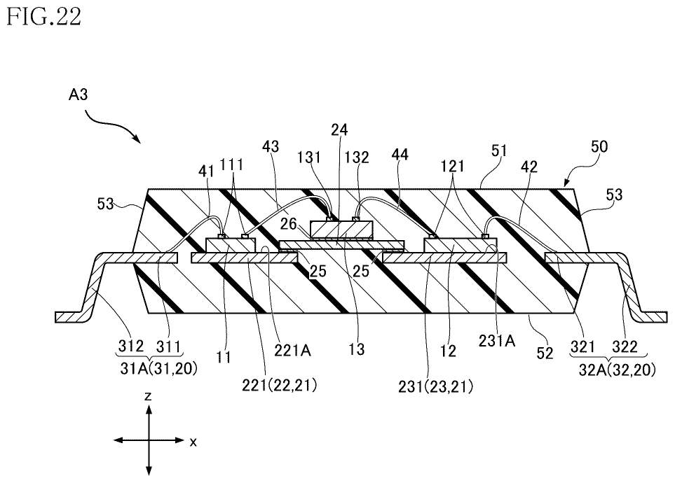

FIGS. 21 and 22 show a semiconductor device according to a third embodiment of the present disclosure. The semiconductor device A3 of the present embodiment has a different arrangement for the insulating substrate 24, compared to the embodiments described above.

In the present embodiment, the insulating substrate 24 spans between the first die pad 22 and the second die pad 23, as viewed in the thickness direction z. The insulating substrate 24 is bonded, at one end, to the first mounting surface 221A of the first die pad 22 and bonded, at the other end, to the second mounting surface 231A of the second die pad 23 by first bonding layers 25.

As viewed in the thickness direction z, the insulating substrate 24 covers at least a part of the gap between the first die pad 22 and the second die pad 23. In the illustrated example, the insulating substrate 24 covers most of the gap between the first die pad 22 and the second die pad 23.

As viewed in the thickness direction z, the insulating element 13 overlaps with the gap between first die pad 22 and second die pad 23. In the illustrated example, the entirety of the insulating element 13 overlaps with the gap between first die pad 22 and second die pad 23.

The present embodiment can also suppresses dielectric breakdown of the insulating element 13. As seen from the present embodiment, the insulating substrate 24 may be bonded only to the first die pad 22, or may be bonded to both the first die pad 22 and the second die pad 23.

### Fourth Embodiment

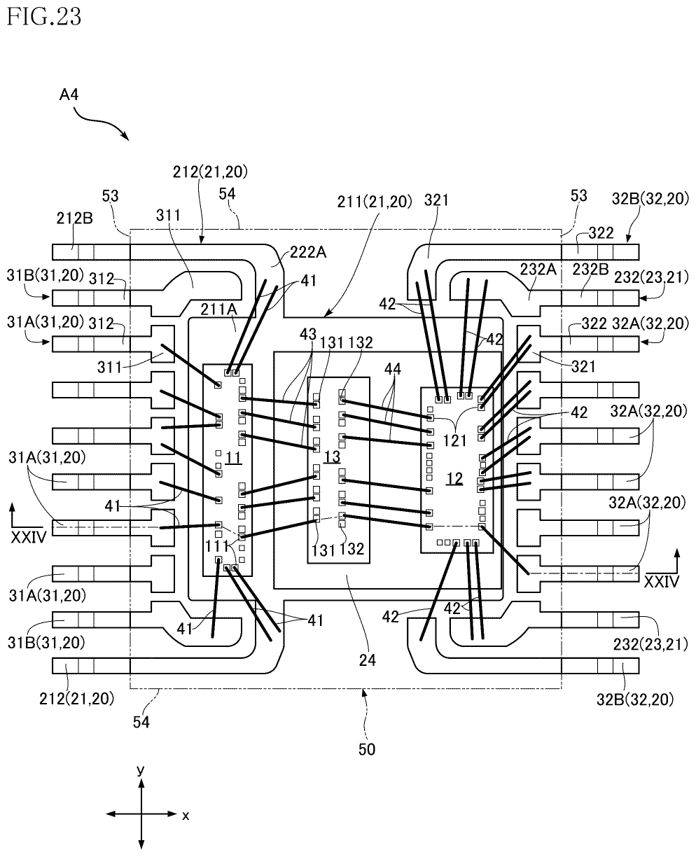

FIGS. 23 and 24 show a semiconductor device according to a fourth embodiment of the present disclosure. The semiconductor device A4 of the present embodiment differs from the above-described embodiments in the configurations of the second semiconductor element 12 and the element support 21.

In the present embodiment, the element support 21 is a single component that does not include a first die pad 22 and a second die pad 23. In the following description, the element support 21 may also be referred to as “die pad 21.” The die pad 21 has a pad portion 211 and two suspension leads 212. The first semiconductor element 11 and the second semiconductor element 12 are disposed on the pad portion 211. The pad portion 211 has a mounting surface 211A facing in the thickness direction z. The first semiconductor element 11 is bonded to the mounting surface 211A via an unillustrated conductive bonding material (such as solder or metal paste). The insulating substrate 24 is bonded to the mounting surface 211A via a first bonding layer 25. The pad portion 211 is covered with the scaling resin 50. The thickness of the pad portion 211 is, for example, not less than 150 μm and not more than 200 μm.

As shown in FIG. 23, the two suspension leads 212 are connected to the respective ends of the pad portion 211 in the second direction y. Each suspension lead 212 has a covered portion 212A and an exposed portion 212B. The covered portion 212A is connected to the pad portion 211 and covered by the sealing resin 50. The covered portion 212A includes a section extending along the first direction x. The exposed portion 212B is connected to the covered portion 212A and exposed from one of the two first side surfaces 53 of the sealing resin 50, on the same side where the exposed portions 312 of the first terminals 31 are exposed. As viewed in the thickness direction z, the exposed portion 212B extends along the first direction x. As viewed in the second direction y, the exposed portion 212B is bent. The surface of the exposed portion 212B may be plated with, for example, tin.

One or more of the first wires 41 are bonded to first electrodes 111 of the first semiconductor device 11 and also to one of the covered portions 212A of the two suspension leads 212. Thus, at least one of the two suspension leads 212 forms a ground terminal electrically connected to the first semiconductor device 11.

The second semiconductor element 12 is bonded to the insulating substrate 24 via a second bonding layer 26. In the semiconductor device A4, the insulating substrate 24 is disposed between the die pad 21 and the pair of the second semiconductor element 12 and the insulating element 13. Further, the second semiconductor element 12 and the insulating element 13 are bonded to the insulating substrate 24. The area of the insulating substrate 24 of this embodiment is great than the area of the insulating substrate 24 of the semiconductor device A1. As viewed in the thickness direction z, the fourth wires 44 are located inward of the periphery 241 of the insulating substrate 24.

As shown in FIG. 23, one or more of the second wires 42 are bonded to second electrodes 121 of the second semiconductor element 12 and also to one or more of the covered portions 321 of the second lateral terminals 32B (second terminals 32). Thus, at least one of the second lateral terminals 32B forms a ground terminal electrically connected to the second semiconductor element 12.

The present embodiment can also suppress dielectric breakdown of the insulating element 13. In the semiconductor device A4, the first semiconductor element 11 is bonded to the pad portion 211 of the die pad 21, while the second semiconductor element 12 is bonded to the insulating substrate 24. Thus, the first semiconductor element 11 and the second semiconductor element 12 are insulated from each other by the insulating element 13 and the insulating substrate 24. Further, since the die pad 21 is a single component, the shape of the die pad 21 can be simplified.

### Fourth Embodiment—First Variation

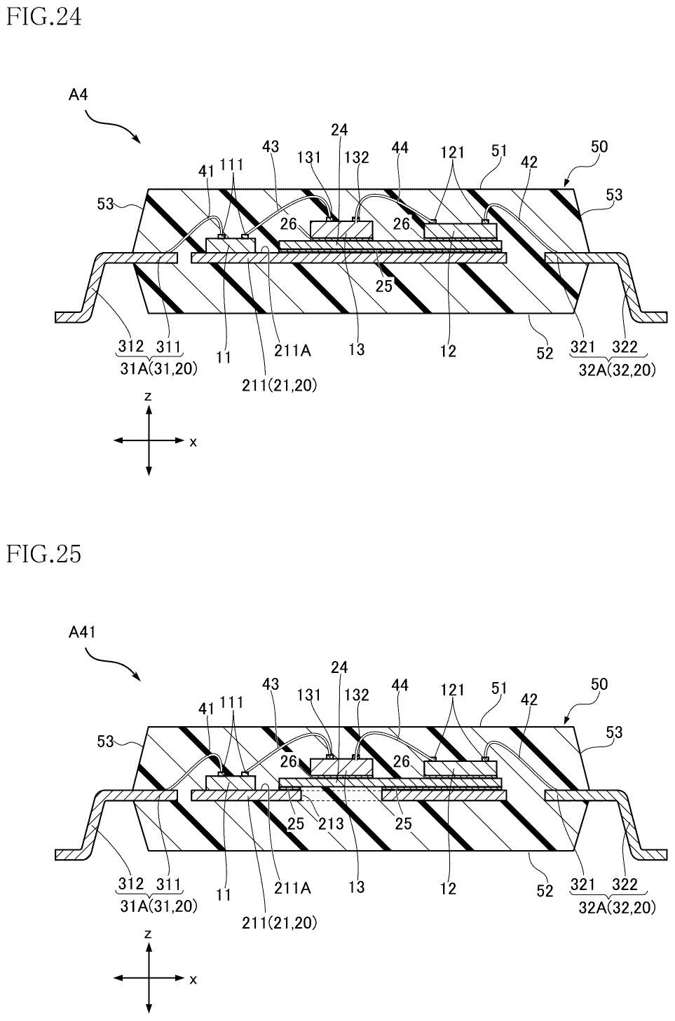

FIG. 25 shows a first variation of the semiconductor device A4. In this variation, the semiconductor device A41 has a die pad (element support) 21 formed with an opening 213, which penetrates through the die pad 21 in the thickness direction z so that it is open at its respective ends in the thickness direction z. The opening 213, as viewed in the thickness direction z, overlaps with the insulating substrate 24. In the illustrated example, the opening 213 is blocked or closed by the insulating substrate 24. The insulating element 13, as viewed in the thickness direction z, overlaps with the opening 213. In the illustrated example, the entirety of the insulating element 13 overlaps with the opening 213.

The dielectric breakdown of the insulating element 13 can also be suppressed by this variation. In this variation, since the die pad 21 has an opening 213, it is possible to make capacitance Ci smaller, which is preferable for suppressing the dielectric breakdown of insulating element 13.

### Fifth Embodiment

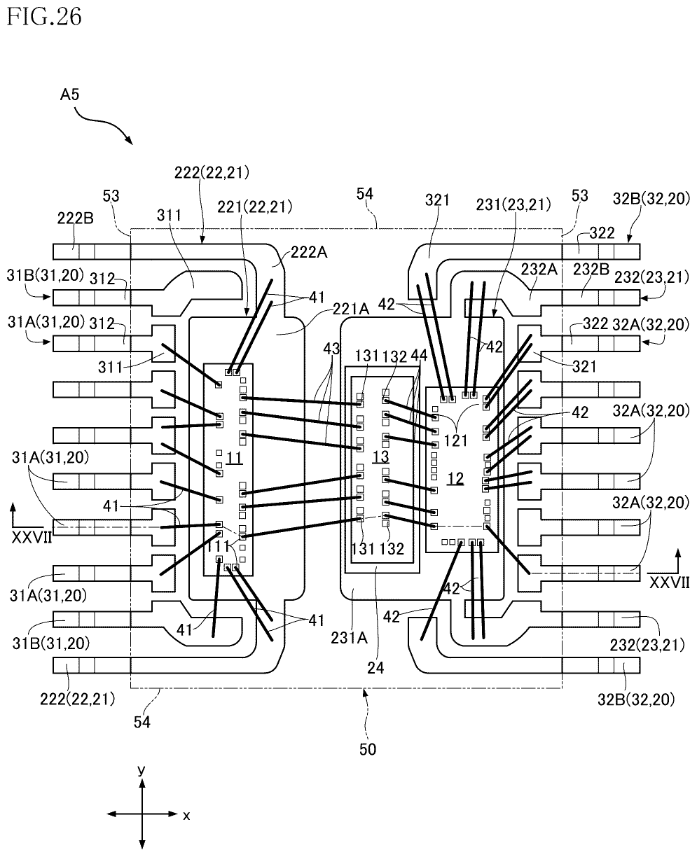

FIGS. 26 to 28 show a semiconductor device according to a fifth embodiment of the present disclosure. The semiconductor device A5 of the present embodiment differs from that of the above-described embodiments in the configurations of the insulating element 13 and the insulating substrate 24.

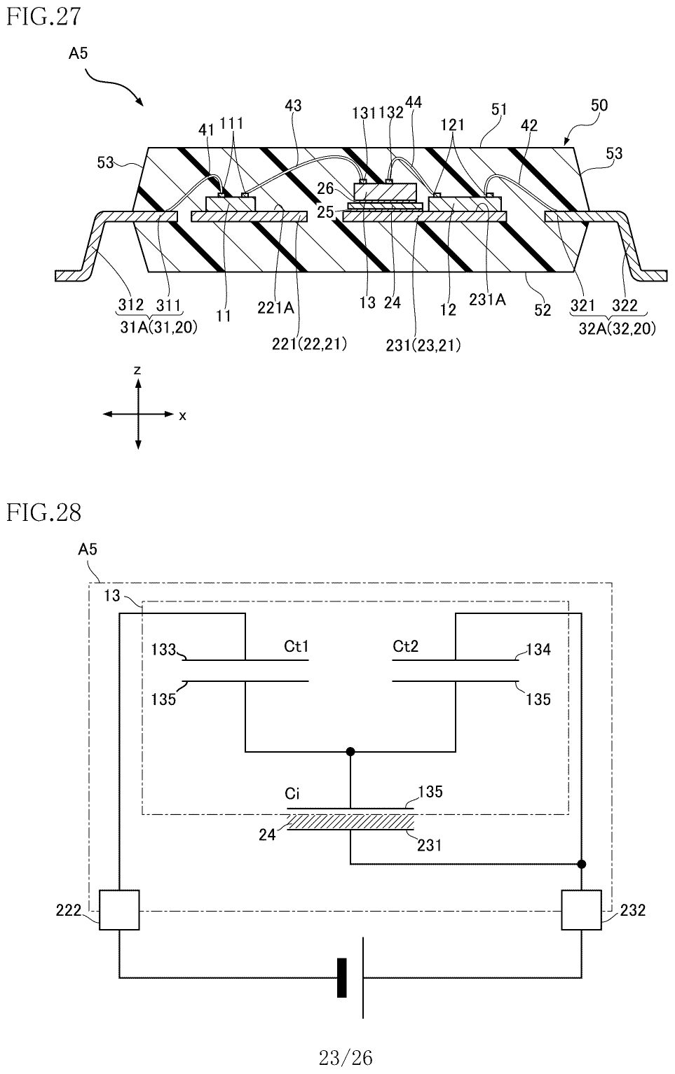

As shown in FIGS. 26 and 27, the insulating substrate 24 is bonded to the second mounting surface 231A of the second pad portion 231 of the second die pad 23. The insulating element 13 is disposed on the second pad portion 231 together with the second semiconductor element 12. As in the semiconductor device A1, the insulating substrate 24 is bonded to the second mounting surface 231A via a first bonding layer 25. Further, as in the semiconductor device A1, the insulating element 13 is bonded to the insulating substrate 24 via a second bonding layer 26. In the semiconductor device A5, third wires 43 bridge between the first pad portion 221 of the first die pad 22 and the second pad portion 231. As seen from this embodiment, even if the potential of the second pad portion 231 is higher than that of the first pad portion 221, the insulating element 13 can be mounted on the second pad portion 231.

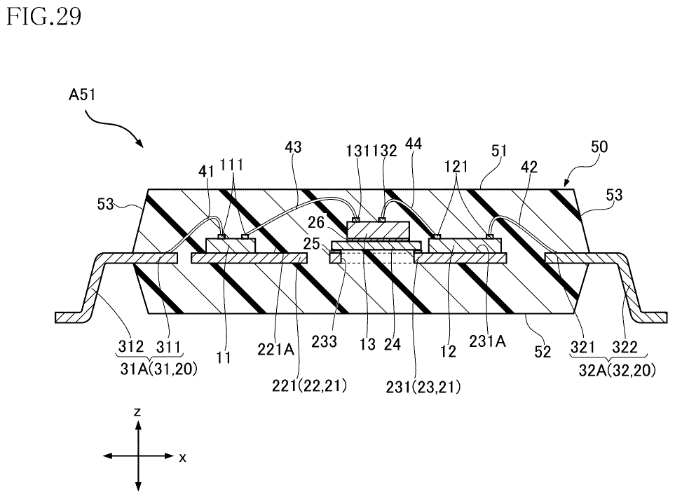

The present embodiment can also suppresses dielectric breakdown of the insulating element 13. As seen from the present embodiment, the configuration of the die pad 21 and the arrangement of the insulating element 13 are not limitative. In the embodiment of FIG. 28, the capacitance Ct2 and the capacitance Ci are connected in parallel, while the capacitance Ct1 is connected in series with the capacitance Ct2 and the capacitance Ci. Thus, it is preferable that the capacitance Ct2 is smaller than the capacitance Ct1.

### Fifth Embodiment—First Variation

FIG. 29 shows a first variation of the semiconductor device A5. In this variation, the semiconductor device A51 has a second die pad 23 formed with a second opening 233. The second opening 233 penetrates through the second die pad 23 in the thickness direction z so that it is open at the respective ends in the thickness direction z. The second opening 233, as viewed in the thickness direction z, overlaps with the insulating substrate 24. In the illustrated example, the second opening 233 is blocked by the insulating substrate 24. The insulating element 13, as viewed in the thickness direction z, overlaps with the second opening 233. In the illustrated example, the entirety of the insulating element 13 overlaps with the second opening 233.

The dielectric breakdown of the insulating element 13 can be suppressed by this variation. With this variation, it is possible to make the capacitance Ci smaller due to the presence of the second opening 233 of the second die pad 23, which is preferable for suppressing the dielectric breakdown of the insulating element 13.

### Sixth Embodiment

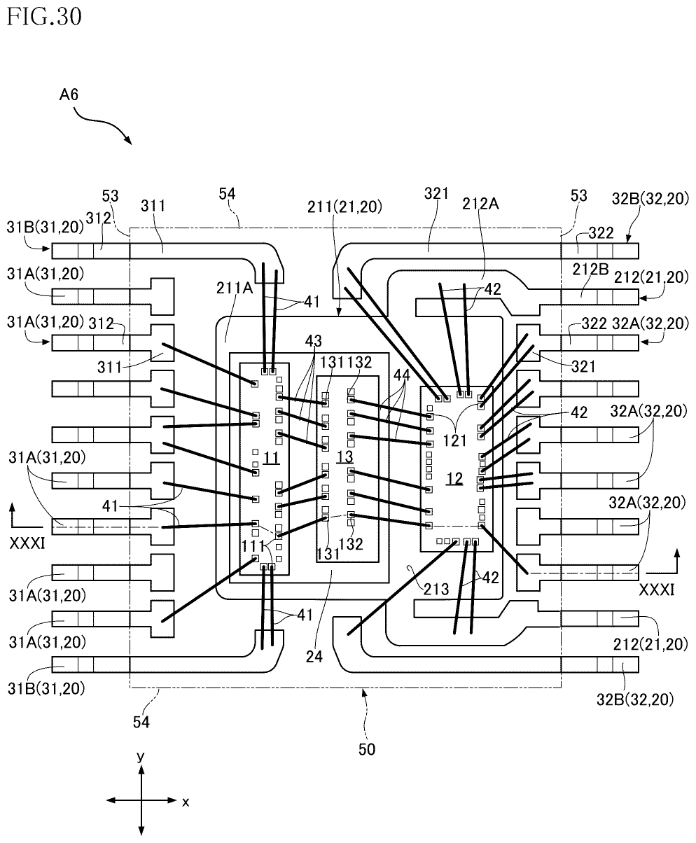

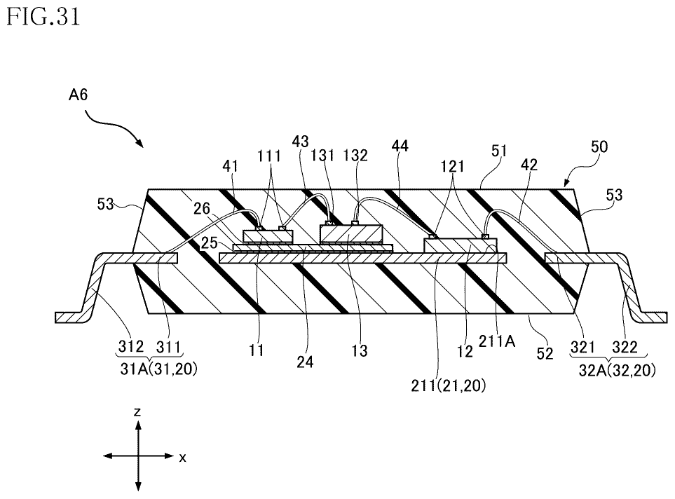

FIGS. 30 and 31 show a semiconductor device according to a sixth embodiment of the present disclosure. The semiconductor device A6 of the present embodiment may differ from the above-described embodiments in the configurations of the insulating element 13, the insulating substrate 24, and the like.

Further, the semiconductor device A6 may differ from the above-described embodiments in the configurations of the first semiconductor element 11, the die pad 21, and the like.

As shown in FIGS. 30 and 31, the die pad 21 is a single component that does not include a first die pad 22 and a second die pad 23, as with the semiconductor device A4. The die pad 21 has a pad portion 211 and two suspension leads 212. The second semiconductor element 12 is bonded to the mounting surface 211A of the pad portion 211 via an unillustrated conductive bonding material (such as solder or metal paste).

As shown in FIG. 30, the exposed portions 212B of the two suspension leads 212 are exposed from one of the two first side surfaces 53 of the sealing resin 50 from which the exposed portions 322 of the second terminals 32 protrude outwards.

As shown in FIG. 30, one or more of the first wires 41 are bonded to first electrodes 111 of the first semiconductor element 11 and to one or more of the covered portions 311 of the two first lateral terminals 31B (first terminals 31). Thus, at least one of the two first lateral terminals 31B serves as a ground terminal connected to the first semiconductor element 11.

As shown in FIG. 30 and FIG. 31, the first semiconductor element 11 is bonded to the insulating substrate 24. The first semiconductor element 11 is bonded to the insulating substrate 24 via a second bonding layer 26, as with the second semiconductor element 12 of the semiconductor device A4. Thus, in the semiconductor device A6, the insulating substrate 24 is disposed between the die pad 21 and the pair of the first semiconductor element 11 and the insulating element 13, with the first semiconductor element 11 and the insulating element 13 being both bonded to the insulating substrate 24. As viewed in the thickness direction z, the third wires 43 are positioned inwards of the periphery 241 of the insulating substrate 24.

As shown in FIG. 30, one or more of the second wires 42 are bonded to second electrodes 121 of the second semiconductor element 12 and to one or more of the covered portions 212A of the two suspension leads 212. Thus, at least one of the two suspension leads 212 serve as a ground terminal electrically connected to the second semiconductor element 12.

The present embodiment can also suppress dielectric breakdown of the insulating element 13. In the semiconductor device A6, the second semiconductor element 12 is bonded to the pad portion 211 of the die pad 21, and the first semiconductor element 11 is bonded to the insulating substrate 24. Thus, the first semiconductor element 11 and the second semiconductor element 12 are mutually insulated by the insulating element 13 and the insulating substrate 24. Further, since the die pad 21 is a single component, the shape of the die pad 21 can be simplified.

The semiconductor devices of the present disclosure are not limited to those of the embodiments/variations described above. The configuration of each part of the semiconductor device of the present disclosure may be varied in many ways. The present disclosure includes the embodiments described in the following clauses.

### Clause 1

A semiconductor device comprising:
a plurality of conductive members including an element support;
a first semiconductor element and a second semiconductor element both disposed on the element support;
an insulating element electrically connected to the first semiconductor element and the second semiconductor element, while also electrically insulating the first semiconductor element and the second semiconductor element from each other; and
an insulating substrate,
wherein the insulating element incudes; a first transceiver electrically connected to the first semiconductor element; a second transceiver electrically connected to the second semiconductor element; and an interfacing member configured to transmit and receive signals between the first transceiver and the second transceiver,
the interfacing member is closer to the element support in a thickness direction of the insulating element than are the first transceiver and the second transceiver,
the insulating substrate is disposed between the element support and the insulating element, and bonded to the element support, and
the insulating element is bonded to the insulating substrate.

### Clause 2

The semiconductor device according to clause 1, wherein the element support includes a first die pad and a second die pad spaced apart from each other,
the first semiconductor element is bonded to the first die pad, and
the second semiconductor element is bonded to the second die pad.

### Clause 3

The semiconductor device according to clause 2, wherein the insulating substrate is bonded to the first die pad.

### Clause 4

The semiconductor device according to clause 3, wherein the first die pad is formed with a first opening overlapping with the insulating substrate as viewed in the thickness direction.

### Clause 5

The semiconductor device according to clause 4, wherein the first opening overlaps with the insulating element as viewed in the thickness direction.

### Clause 6

The semiconductor device according to clause 5, wherein the first opening overlaps with an entirety of the insulating element as viewed in the thickness direction.

### Clause 7

The semiconductor device according to any one of clauses 2-6, wherein a capacitance between the first transceiver and the interfacing member is smaller than a capacitance between the second transceiver and the interfacing member.

### Clause 8

The semiconductor device according to clause 2, wherein the insulating substrate is bonded to the second die pad.

### Clause 9

The semiconductor device according to clause 8, wherein the second die pad is formed with a second opening overlapping with the insulating substrate as viewed in the thickness direction.

### Clause 10

The semiconductor device according to clause 9, wherein the second opening overlaps with the insulating element as viewed in the thickness direction.

### Clause 11

The semiconductor device according to clause 10, wherein the second opening overlaps with an entirety of the insulating element as viewed in the thickness direction.

### Clause 12

The semiconductor device according to any one of clauses 8-11, wherein a capacitance between the second transceiver and the interfacing member is smaller than a capacitance between the first transceiver and the interfacing member.

### Clause 13

The semiconductor device according to clause 1, wherein the first semiconductor element is bonded to the insulating substrate.

### Clause 14

The semiconductor device according to clause 1, wherein the second semiconductor element is bonded to the insulating substrate.

### Clause 15

The semiconductor device according to clause 14, wherein the element support is formed with an opening overlapping with the insulating substrate as viewed in the thickness direction.

### Clause 16

The semiconductor device according to clause 15, wherein the opening overlaps with the insulating element as viewed in the thickness direction.

### Clause 17

The semiconductor device according to clause 16, wherein the opening overlaps with an entirety of the insulating element as viewed in the thickness direction.

### REFERENCE NUMERALS

A1, A11, A2, A21, A22, A3: Semiconductor device A4, A41, A5, A51, A6: Semiconductor device 11: First semiconductor element 12: Second semiconductor element 13: Insulating element 13A: First insulating element 13B: Second insulating element 20: Conductive member 21: Element support (die pad) 22: First die pad 23: Second die pad 24: Insulating substrate 25: First bonding layer 26: Second bonding layer 31: First terminal 31A: First intermediate terminal 31B: First lateral terminal 32: Second terminal 32A: Second intermediate terminal 32B: Second lateral terminal 41: First wire 42: Second wire 43: Third wire 44: Fourth wire 45: Fifth wire 50: Sealing resin 51: Top surface 52: Bottom surface 53: First side surface 54: Second side surface 111: First electrode 121: Second electrode 131: First relay electrode 132: Second relay electrode 133: First transceiver 134: Second transceiver 135: Interfacing member 135A: First interfacing member 135B: Second interfacing member 136: Third relay electrode 137: Fourth relay electrode 211: Pad portion 211A: Mounting surface 212: Suspension lead 212A: Covered portion 212B: Exposed portion 213: Opening 221: First pad portion 221A: First mounting surface 222: First suspension lead 222A: Covered portion 222B: Exposed portion 223: First opening 231: Second pad portion 231A: Second mounting surface 232: Second suspension lead 232A: Covered portion 232B: Exposed portion 233: Second opening 241: Periphery 311: Covered portion 312: Exposed portion 321: Covered portion 322: Exposed portion 531: First upper portion 532: First lower portion 533: First middle portion 541: Second upper portion 542: Second lower portion 543: Second middle portion Ci, Ct1, Ct2: Capacitance T, t1, t2: Thickness x: First direction y: Second direction z: Thickness direction

1. A semiconductor device comprising:
a plurality of conductive members including an element support;
a first semiconductor element and a second semiconductor element disposed on the element support;
an insulating element electrically connected to the first semiconductor element and the second semiconductor element and electrically insulating the first semiconductor element and the second semiconductor element from each other; and
an insulating substrate,
wherein the insulating element incudes; a first transceiver electrically connected to the first semiconductor element; a second transceiver electrically connected to the second semiconductor element; and an interfacing member configured to transmit and receive signals between the first transceiver and the second transceiver,
the interfacing member is closer to the element support in a thickness direction of the insulating element than are the first transceiver and the second transceiver,
the insulating substrate is disposed between the element support and the insulating element and bonded to the element support, and
the insulating element is bonded to the insulating substrate.

2. The semiconductor device according to claim 1, wherein the element support includes a first die pad and a second die pad spaced apart from each other, the first semiconductor element is bonded to the first die pad, and the second semiconductor element is bonded to the second die pad.

3. The semiconductor device according to claim 2, wherein the insulating substrate is bonded to the first die pad.

4. The semiconductor device according to claim 3, wherein the first die pad is formed with a first opening overlapping with the insulating substrate as viewed in the thickness direction.

5. The semiconductor device according to claim 4, wherein the first opening overlaps with the insulating element as viewed in the thickness direction.

6. The semiconductor device according to claim 5, wherein the first opening overlaps with an entirety of the insulating element as viewed in the thickness direction.

7. The semiconductor device according to claim 2, wherein a capacitance between the first transceiver and the interfacing member is smaller than a capacitance between the second transceiver and the interfacing member.

8. The semiconductor device according to claim 2, wherein the insulating substrate is bonded to the second die pad.

9. The semiconductor device according to claim 8, wherein the second die pad is formed with a second opening overlapping with the insulating substrate as viewed in the thickness direction.

10. The semiconductor device according to claim 9, wherein the second opening overlaps with the insulating element as viewed in the thickness direction.

11. The semiconductor device according to claim 10, wherein the second opening overlaps with an entirety of the insulating element as viewed in the thickness direction.

12. The semiconductor device according to claim 8, wherein a capacitance between the second transceiver and the interfacing member is smaller than a capacitance between the first transceiver and the interfacing member.

13. The semiconductor device according to claim 1, wherein the first semiconductor element is bonded to the insulating substrate.

14. The semiconductor device according to claim 1, wherein the second semiconductor element is bonded to the insulating substrate.

15. The semiconductor device according to claim 14, wherein the element support is formed with an opening overlapping with the insulating substrate as viewed in the thickness direction.

16. The semiconductor device according to claim 15, wherein the opening overlaps with the insulating element as viewed in the thickness direction.

17. The semiconductor device according to claim 16, wherein the opening overlaps with an entirety of the insulating element as viewed in the thickness direction.
